(19) United States
(12) Patent Application Publication
(10) Pub. No.: US 2005/0128327 A1
(43) Pub. Date: Jun. 16, 2005

(54) Device and method for image sensing

(76) Inventors: Selim S. Bencuya, Irvine, CA (US); Jiafu Luo, Thousand Oaks, CA (US); Richard A. Mann, Torrance, CA (US)

Correspondence Address: MILBANK, TWEED, HADLEY & MCCLOY LLP, 1 CHASE MANHATTAN PLAZA, NEW YORK, NY, 10005-1413, US

(21) Appl. No.: 10/732,583

(22) Filed: Dec. 10, 2003

(51) Int. Cl. H04N 3/14; H04N 5/335; H01L 27/00

(52) U.S. Cl. 348/308; 348/294; 250/208.1

(57) ABSTRACT

The present invention relates to devices and methods for image sensing. In one aspect, the present invention relates to a device including a plurality of pixels, wherein each pixel includes a charge transfer device and photodetector, and each of the pixels has a pitch of about 3 microns or less. This aspect further includes a select transistor, a reset transistor, a source follower transistor, and a sense node, wherein the select transistor, the reset transistor, the source follower transistor, and the sense node are shared by the plurality of pixels.

### FIELD OF THE INVENTION

The present invention generally relates to imaging technology and, more particularly, to solid state devices and methods for sensing images using a number of pixels.

### BACKGROUND OF THE INVENTION

Certain conventional image sensing devices have been used to convert an image into a signal indicative of the image. Conventional image sensing technology includes certain charge coupled devices (“CCD”), certain complimentary metal oxide semiconductors (“CMOS”), and other devices.

In recent years, for certain applications and users, CMOS image sensing devices have become practical and provide cost and power advantages over other technologies, such as CCD. Conventional CMOS image sensing devices have been fabricated from semiconductor materials and include imaging arrays of light detecting (i.e., photosensitive) elements called “photodetectors.” Such photodetectors have been used to generate analog signals representative of a particular image presented to the device, and conventional imaging arrays have included a number of photodetectors arranged into rows and columns. In these conventional devices, each photodetector corresponds to a picture element or “pixel” of an imaging array and receives a portion of the total amount of light reflected from an object.

In certain conventional CMOS image sensing devices, each photodetector of an imaging array may be reset to an approximately known potential after readout of a previous image, and in preparation for the next image. However, such conventional CMOS image sensing devices may have drawbacks for particular applications and users. For example, some conventional CMOS image sensing devices suffer from noise associated with the process for resetting each photodiode to a known potential after each exposure and in preparation for the next image. This noise, which is associated with the gate capacitor of a field effect transistor (“FET”), has been referred to as “reset noise” or “KTC noise,” and can be a significant source of noise in camera systems that employ conventional CMOS image sensing technology.

It has been documented that reset noise is proportional to the square root of kT/C, where k is Boltzmann's constant, T is the temperature of the device, and C is the FET gate switch capacitance (e.g., a sensing node or a photodiode/source follower gate combination as used in certain conventional active pixel sensing devices). Reset noise in certain conventional image sensors may be 20 to 40 electrons of uncertainty one-sigma. Reducing the capacitance of the sensing node may reduce reset noise in some devices, but it may also cause a corresponding reduction in the total charge that can be collected—thereby undesirably reducing the overall dynamic range in the camera system.

Conventional correlated double sampling (“CDS”) is a generic term used to describe techniques for canceling reset noise in some conventional CMOS image sensing devices. To facilitate conventional CDS, separate photodiode nodes and sense nodes may be used. Such a photodiode is reset prior to an “exposure” or integration of collected photo charges in order to be fully depleted of mobile carriers. Using certain conventional CDS techniques, a CMOS image sensing device may read and store an original or “reference” charge level on a sense node immediately after reset. This reset of the sense node and storage of the reference charge level typically occurs near the end of an exposure period (i.e., after an integration period) and immediately prior to readout of a signal from the photo-charges collected by the photodiode. A final charge level of each photodetector may then be transferred to a sensing node, read, and the reference charge level then subtracted from the final charge level. In this manner, image-distorting offsets associated with reset noise can be cancelled.

Employing conventional CDS, however, typically requires additional circuitry, such as additional transistors and signal lines to control transistor functions. Such additional circuitry may occupy significant area on a semiconductor chip and reduce the detecting area associated with the photodetectors. For this reason, the additional circuitry may be difficult to accommodate in a device that has a small pixel pitch and, as a consequence, reset noise may be reduced at the cost of some signal loss. Some conventional three-transistor-active-pixel image sensing devices implemented in CMOS may require only three transistors and four wires, but such devices do not support conventional CDS operations. Addition of at least a fourth transistor and increase of the wire count to at least five has been necessary to allow conventional CDS operation to be performed in certain conventional image sensing devices.

### SUMMARY OF THE INVENTION

In one aspect, the invention features a device including a plurality of pixels, wherein each pixel includes a charge transfer device and a photodetector, and each of the pixels has a pitch of about 3 microns or less. This aspect further includes a select transistor, a reset transistor, a source follower transistor, and a sense node, wherein the select transistor, the reset transistor, the source follower transistor, and the sense node are shared by the plurality of pixels.

In another aspect, the invention features an active pixel CMOS image sensor circuit including a plurality of pixels, wherein each pixel includes a photodiode coupled with a transfer transistor. This aspect also includes a shared sense node coupled with each of the transistors, a reset transistor having a source coupled with the shared sense node, a source follower transistor having a drain coupled with a drain of the reset transistor and a gate coupled with the shared sense node, and a select transistor having a drain coupled with a source of the source follower transistor. In this aspect, the select transistor, the reset transistor, the source follower transistor, and the sense node are shared by the plurality of pixels, wherein each of the plurality of pixels has a pitch of about three microns or less, and wherein each photodetector is capable of being substantially fully depleted and each charge transfer device is capable of transferring substantially all of a charge presented thereto.

In a further aspect, the invention features a shared readout circuit for reading a plurality of photodetectors, the shared readout circuit including a shared sense node coupled with a plurality of transfer transistors, each of the plurality of transfer transistors configured to transfer substantially all of a charge from a corresponding one of the photodetectors to the shared sense node and connecting a corresponding one of the plurality of photodetectors to the shared sense node, the shared sense node configured to store a charge collected by each of the plurality of photodetectors. This aspect also includes a reset transistor, a source follower transistor, and a select transistor, the reset transistor being connected to the shared sense node and configured to reset the shared sense node, the source follower transistor having a gate connected to the shared sense node, and the select transistor connecting the source follower transistor to a common bus.

In yet another aspect, the invention features a CMOS image sensor circuit including a plurality of photodiodes, each of the plurality of photodiodes associated with a pixel of an imaging array, the pixel having a pitch of about 3 microns or less, and a plurality of transfer transistors, each of the plurality of transfer transistors connecting a corresponding one of the plurality of photodiodes to a shared sense node, the shared sense node configured to store a charge collected by each of the plurality of photodiodes. This aspect further includes a shared readout circuit including a reset transistor, a source follower transistor, and a select transistor, the reset transistor being connected to the shared sense node and configured to reset the shared sense node. In this aspect, the source follower transistor has a gate connected to the shared sense node, and the select transistor connects the source follower transistor to a common bus.

In still another aspect, the invention features a CMOS image sensor circuit including a group of four photodiodes that share a common readout pathway through a common sense node, wherein each of the photodiodes is connected to the common sense node through an individual transfer device and is associated with a pixel that has a pitch of about 3 microns or less, the common sense node is connected to a common source follower FET which is selected for readout by a common select FET, and the common sense node is connected to a common reset FET to establish positive potential on the sense node and each photodiode.

### BRIEF DESCRIPTION OF THE DRAWINGS

The foregoing features and other aspects of the invention are explained in the following description taken in connection with the accompanying drawings, wherein:

FIG. 1 depicts a schematic diagram of an image sensor circuit 100-1 according to one embodiment of the present invention;

FIGS. 2A-2D depict timing diagrams for use in operating the image sensor circuit 100-1 of FIG. 1 according to one example method embodiment of the present invention;

FIG. 3 depicts a block diagram of a portion of a repeating four-pixel shared layout 300 including, according to one embodiment, the image sensor circuit 100-1 of FIG. 1;

FIG. 4 depicts a block diagram of a portion of another semiconductor chip 400 embodiment of the present invention;

FIG. 5 depicts a block diagram of a portion of yet another semiconductor chip 500 embodiment of the present invention;

FIG. 6 depicts a block diagram of a digital camera 60 according to one embodiment of the present invention; and

FIG. 7 depicts a block diagram of mobile phone 70 according to one embodiment of the present invention.

The drawings are exemplary and are not to be deemed limiting to the full scope of the appended claims.

### DETAILED DESCRIPTION OF PREFERRED EMBODIMENTS

Various embodiments of devices, systems, and methods in accordance with the present invention will now be described with reference to the drawings.

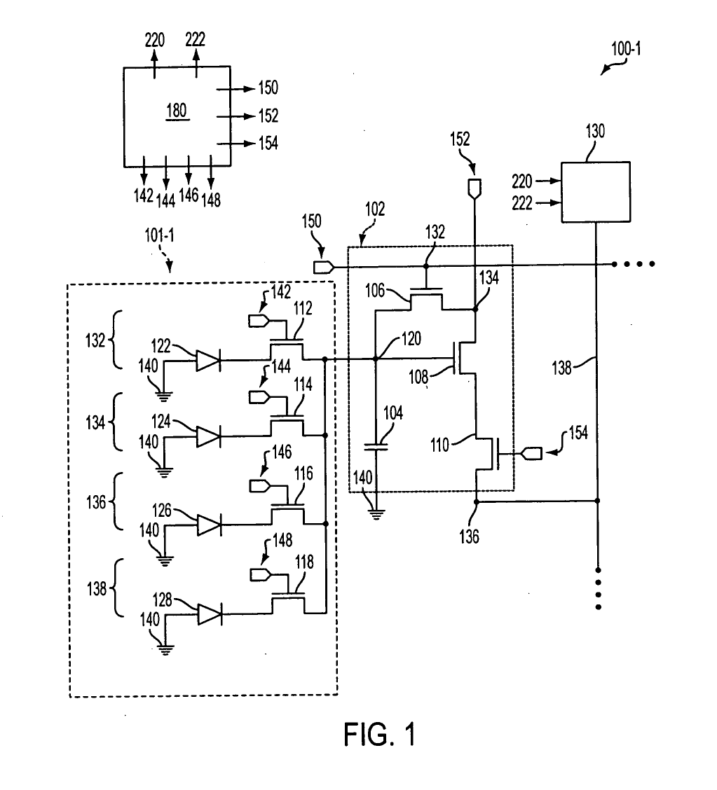

FIG. 1 shows a schematic diagram of an image sensor circuit 100-1 according to one embodiment of the invention. This embodiment of the image sensor circuit 100-1 includes a shared readout circuit 102 that generally includes a shared sense node 120, a reset device 106, a source follower device 108, and a select device 110. The image sensor circuit 100-1 of one embodiment may be used in a variety of applications including imaging devices such as a digital camera 60 or a mobile phone 70. One embodiment of an image sensor circuit 100-1 may be configured to control and read a plurality of pixels 132, 134, 136, 138, each of which is a single addressable point that produces picture information. In this embodiment, each pixel 132, 134, 136, 138 includes a photodetector 122, 124, 126, 128 and a transfer device 142, 144, 146, 148. In one preferred embodiment, the image sensor circuit 100-1 is implemented as a CMOS chip 300.

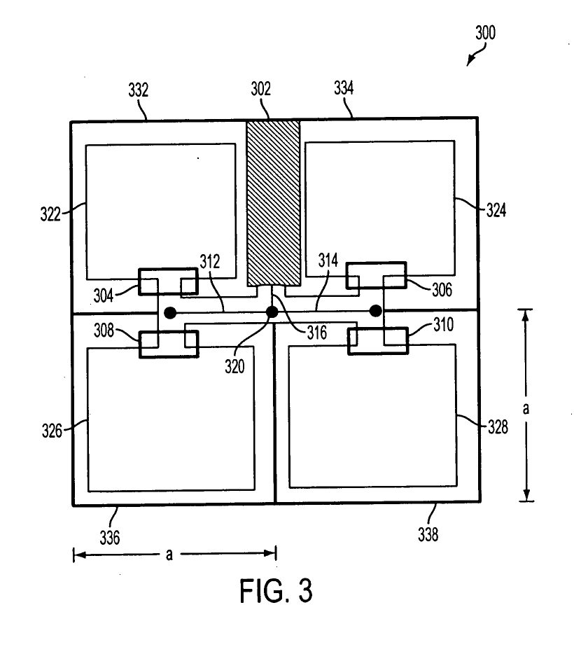

Each pixel 132, 134, 136, 138 of the embodiment shown in FIGS. 1 and 3 collects photo-charges trapped in the pixel 132, 134, 136, 138. The photo-charges are proportional to the radiation intensity falling upon the detecting area 322, 324, 326, 328 of the pixel 332, 334, 336, 338 (see FIG. 3). A detecting area is defined by the physical dimensions of the pixel's 332, 334, 336, 338 corresponding photodetector 322, 324, 326, 328. The photo-charges from each pixel 332, 334, 336, 338 are converted to a charge signal, which is an electrical potential representative of the photon intensity reflected from a respective portion of an object that is received by the image sensor circuit 100-1. The resulting charge signal or potential may be read and processed by video/image processing circuitry 65, 75 or other circuitry to create a signal representation of the image.

The image sensor circuit 100-1 shown in FIG. 1 includes a group of pixels 101-1 which provide light information from four adjacent photodiodes 122, 124, 126, 128. An imaging device, such as a digital camera 60 or a mobile phone 70 according to embodiments of the present invention, may contain many groups of pixels 101-1 to 101-N and corresponding image sensor circuits 100-1 to 100-N to provide a total resolution for the imaging device. Such groups of pixels 101-1 to 101-N may be arranged in rows and columns to form an imaging array: As shown in FIG. 3, a group of pixels may be arranged so that two pixels 332, 334 are contained in an odd row and two pixels 336, 338 are contained in an even row. According to this embodiment, each column of pixels 332, 336 may have column circuitry that includes a sample and hold circuit 130 to capture data from pixels 332, 336 in the particular column.

The image sensor circuit 100-1 shown in FIG. 1 is configured to control and read photodiodes 122, 124, 126, 128, although other types of photodetectors (e.g., photogates) may also be used with the present invention. Each photodiode 122, 124, 126, 128 of the embodiment of FIG. 1 is associated with at least one pixel in an imaging array of an imaging device. Although four photodiodes 122, 124, 126, 128 are shown in the image sensor circuit 100-1 of FIG. 1, an image sensor circuit 100-1 may control and read more or fewer photodiodes and pixels.

As shown in FIG. 1, each photodiode 122, 124, 126, 128 may be coactively coupled to ground 140 through the shared sense node 120 of the shared readout circuit 102 by a corresponding transfer transistor 112, 114, 116, 118. The capacitor 104 shown in FIG. 1 represents a junction capacitance and other capacitance elements of the shared sense node 120. Each of the transfer transistors 112, 114, 116, 118, as well as a reset transistor 106, source follower transistor 108, and select transistor 110 may include an N-channel field effect transistor (NFET).

In the image sensor circuit 100-1 shown in FIG. 1, the drain of the reset transistor 106, is tied to the drain of the source follower transistor 108 at a “cell high” circuit node 134, and the source of the reset transistor 106 is connected to the gate of the source follower transistor 108 at the shared sense node 120. Also, as shown in FIG. 1, the source of the source follower transistor 108 is connected to the drain of the select transistor 10, and the source of the select transistor 110 is coupled at another circuit node 136 to another readout circuit (e.g., a sample and hold circuit 130) via a common bus 138.

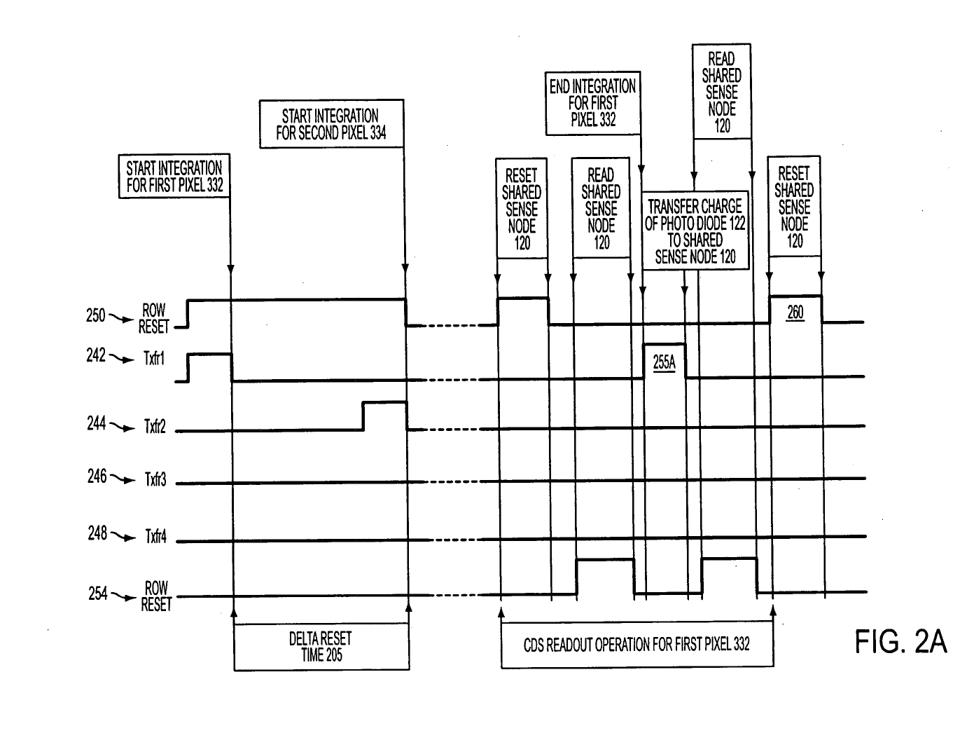

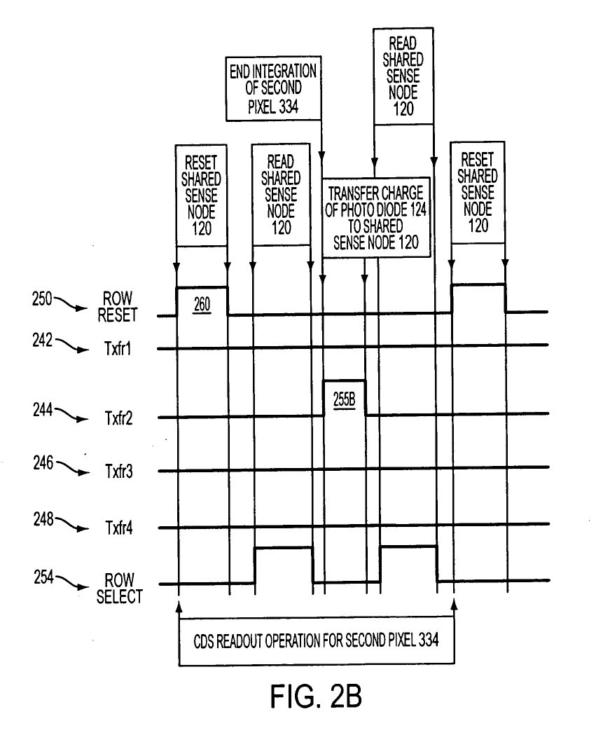

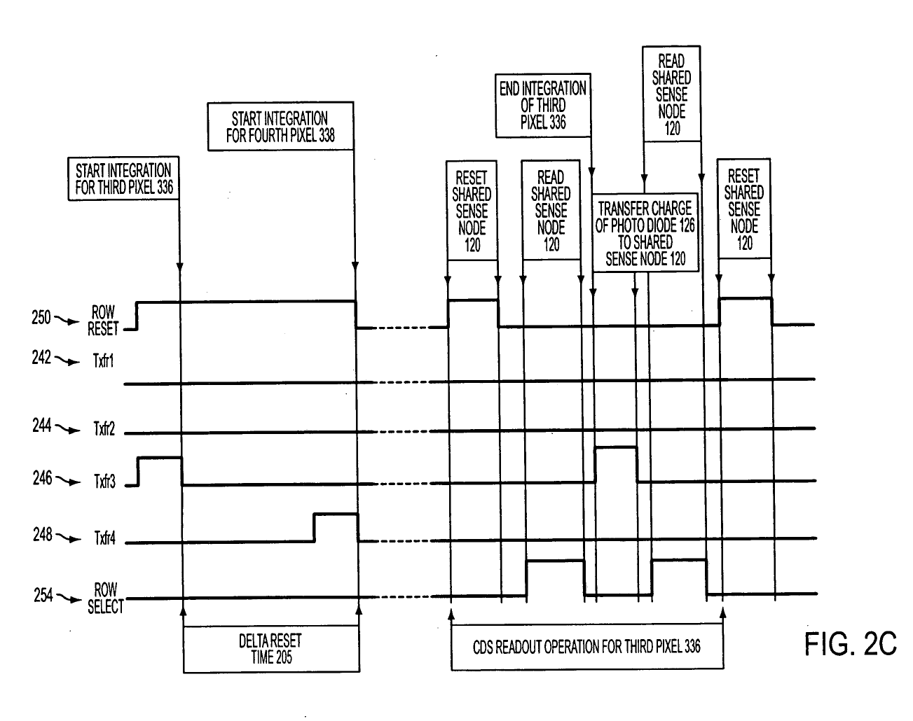

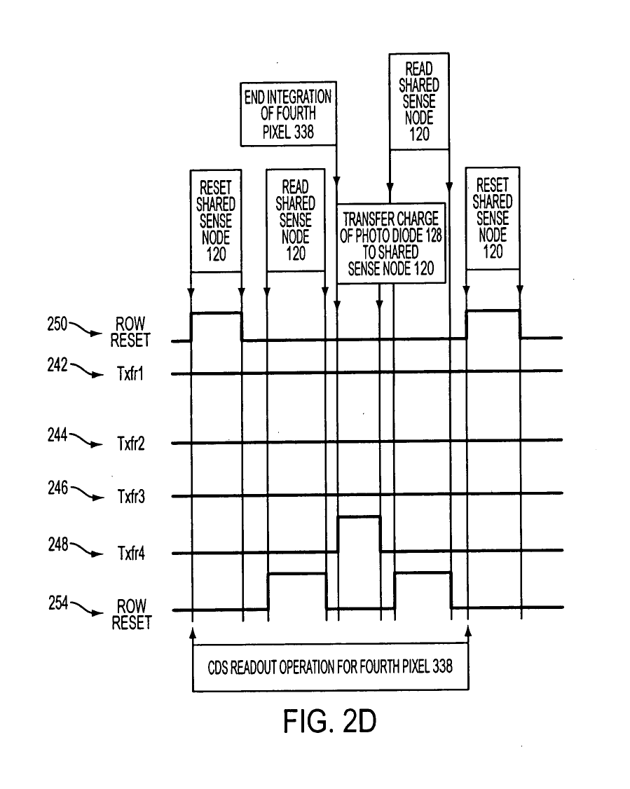

In the embodiment shown in FIG. 1, a controller 180 may provide control and timing signals to each of the transfer transistors 112, 114, 116, 118, the reset transistor 106, the source follower transistor 108, the select transistor 110 and the sample and hold circuit 130. In one embodiment, the controller 180 generates signals and waveforms to effect the timing shown in FIGS. 2A-2D. For example, the controller 180 may supply a “cell high” signal 152 to the “cell high” circuit node 134, a “row reset” signal 150 to the gate of the reset transistor 106, a “row select” signal 154 to the gate of the select transistor 110, a first transfer signal (“Txfr1”) 142 to the gate of a first transfer transistor 112, a second transfer signal (“Txfr2”) 144 to the gate of a second transfer transistor 114, a third transfer signal (“Txfr3”) 146 to the gate of a third transfer transistor 116, and a fourth transfer signal (“Txfr4”) 148 to the gate of a fourth transfer transistor 118. Operation of the sample and hold circuit 130 may also be controlled by signals (SH1 220 and SH2 222) supplied by the controller 180.

FIGS. 2A-2D show block diagrams of a method of sensing an image according to one embodiment of the present invention and, in particular, one preferred method of timing and control used to operate the image sensor circuit 100-1 of FIG. 1. In FIGS. 2A-2D, a row reset signal 250 corresponds to the row reset signal 150 applied to the gate of the reset transistor 106 shown in FIG. 1. A row select signal 254 corresponds to the row select signal 154 applied to the gate of the select transistor 110. A signal labeled “Txfr1” 242 corresponds to the first transfer signal 142, which is applied to the gate of a first transfer transistor 112 in the depicted embodiment. A signal labeled “Txfr2” 244 corresponds to the second transfer signal 144, which is applied to the gate of a second transfer transistor 114. A signal labeled “Txfr3” 246 corresponds to the third transfer signal 146, which is applied to the gate of a third transfer transistor 116. A signal labeled “Txfr4” 248 corresponds to the fourth transfer signal 148, which is applied to the gate of a fourth transfer transistor 118.

FIG. 2A illustrates timing for resetting, reading, and controlling a first pixel, for example pixel 332 as shown in FIG. 3 (contained in an odd row). FIG. 2B illustrates timing events for resetting, reading, and controlling a second pixel, for example pixel 334 as shown in FIG. 3 (contained in an odd row).

At the beginning of a cycle according to one method embodiment, a sense node for a first pixel 332 (corresponding, for example, with the shared sense node 120 of the embodiment shown in FIG. 1) is reset by switching high the row reset signal (250, 150) to the gate of the reset transistor 106 and then setting high a first transfer signal (Txfr1 242, 142). This action resets the first pixel 332 and starts the “integration time” or exposure time for the first pixel 332. After a delay that corresponds to the time required to complete the CDS readout operation (which in one embodiment may be about 40 clock cycles), referred to as the “delta reset time” 205 illustrated in FIG. 2A, a second transfer signal (Txfr2 244, 144) is held high while the master reset signal is also held high to reset a second pixel 334. This action resets the second pixel 334 and starts the integration time or exposure time for the second pixel 334. The offset in time between these events, i.e., the delta reset time 205, allows the first pixel's 332 information to later be fully read out prior to the readout of the second pixel's 334 information. This delta reset time 205 thus allows the sense node 120 and source follower device 108 to be shared. In such an embodiment, the delta reset time 205 may be adjusted and may be preferably on the order of less than 10 microseconds to help avoid significant image artifacts. In such an embodiment, exposure durations may include the range of about one millisecond to greater than about thirty milliseconds.

The delta reset time 205 is also equal to the required delay between a pulse 225A in the Txfr1 signal 242 shown in FIG. 2A and a pulse 255B in the Txfr2 signal 244 shown in FIG. 2B (to ensure that the integration time for both pixels is equal). As shown, this pulse 255A in the Txfr1 signal 242 ends the integration of a first pixel 332 and the signal charge of the photodiode 122 may then be transferred to the shared sense node 120 for readout. The pulse 255B in the Txfr2 signal 244 of a second pixel 334 ends the integration of the second pixel 334 and the signal charge of the photodiode 124 may then be transferred to the shared sense node 120. A pulse 260 in the row reset signal 250 is illustrated in both FIGS. 2A and 2B, and is the identical pulse for resetting the shared sense node 120. Before the end of an integration period (which in one embodiment may vary in length and be set by the particular imaging device that includes an embodiment of the image sensor circuit 100-1), the row reset signal 250 may be held high to reset the shared sense node 120. Then, after a short delay, a row select signal 245 is held high and the reference voltage of the shared sense node 120 is sampled to the sample and hold circuit 130 for the particular column. This reference voltage may contain the DC offset for the column and the KTC noise of the reset of the shared sense node 120. In one embodiment, a current source may be connected to a circuit node 136 to source 4 to 20 micro amps during the read process. The bus voltage of the common bus 138 may then be set by the voltage on the source follower device 108 and, as during readout, this is the only row of the imaging array having the row select transistor 110 turned on, and current flows from “cell high” through circuit nodes 134 and 136.

After integration, the gate of the first transfer device 112, may be held high to transfer the charge integrated on a first photodiode 122 to the shared sense node 120. After the charge transfer is complete, the first transfer signal (Txfr1 242, 142) is returned to the off or low state and the row select signal 254 is held high. While the row select signal 254 is held high, the voltage on the shared sense node 120 is read out to a second capacitor in the sample and hold circuit 130 of the associated column. This second capacitor in the column now holds a voltage which is proportional to the integrated light signal, plus the KTC noise of the shared sense node 120, plus the DC offsets of the column. This summed voltage may be subtracted later from the voltage stored on the first capacitor in the sample and hold circuit 130 to yield a final voltage, which is proportional only to the integrated light signal. In this manner, the example first photodiode 122 in an odd row has been reset, collected light, and the light signal read out using CDS of the shared sense node 120 such that the KTC noise of the reset is removed from the final signal.

Alternate variations of the signal timing and relative placement of the individual signal pulses during the CDS operation for the pixel may be elected. This example shows how the timing and control can be implemented to allow sharing of the master select transistor 154, source follower transistor 110, and shared sense node 120 while maintaining the features of typical CMOS image exposure control.

FIG. 2B shows a cycle occurring for a second photodiode 124 located in the same example odd row as the first photodiode 122. The readout of this second photodiode 124 occurs a short time after that of the first photodiode 122. In one embodiment, this delay interval is equal to the delta reset time 205, which allows sharing of the shared sense node 120.

The other two photodiodes (i.e., photodiodes 126 and 128) of the particular group of four pixels shown in FIG. 1 reside in an even row. After the odd row has been completely read, the next even row will be read in a similar manner, as illustrated in FIGS. 2C and 2D. FIG. 2C illustrates timing events on an even row for a third pixel 336, and FIG. 2D illustrates timing events on an even row for a fourth pixel 338. In accordance with embodiments of the present invention, the delay between reading the first and second photodiodes of a given group of pixels in a specific row can be set in a variety of manners and for a variety of times while still allowing the reset transistor 106, shared sense node 120, source follower transistor 108, and select transistor 110 to be shared without introduction of significant image artifacts.

According to one embodiment, each photodiode 122, 124, 126, 128 is fully depleted during readout and each corresponding transfer device 112, 114, 116, 118 efficiently transfers to the shared sense node 120 substantially all of the charge stored on the photodiode 122, 124, 126, 128. As a result, reset noise in the image sensor circuit 100-1 can be minimized.

The technique depicted in FIGS. 2A-2D for controlling and reading photodiodes 122, 124, 126, 128 using the shared readout circuit 102 shown in FIG. 1 may result in significantly improved image quality due to the improved signal to noise ratio (SNR) achieved by the image sensor circuit 100-1. The noise in an overall system that includes the image sensor circuit 100-1 of one embodiment may be as low as 10 electrons of uncertainty one-sigma. Improved SNR of one embodiment is achieved by using the technique discussed above while providing an increased detecting area for each photodiode 122, 124, 126, 128. For example, in order to achieve CDS for four photodiodes, certain conventional CMOS image sensing devices require a total of sixteen transistors, i.e., four transistors for each photodiode. In contrast, the image sensor circuit 100-1 according to one embodiment of the present invention may achieve CDS using as few as seven transistors in total. As a result of the reduced transistor requirement of the image sensor circuit 100-1, the silicon area consumed for carrying out control and readout of the photodiodes 122, 124, 126, 128 may be significantly reduced and, therefore, the associated light detecting area associated with each photodiode 122, 124, 126, 128 may be increased. The increased light detecting area for the photodiodes 122, 124, 126, 128 of one embodiment is believed to enable significantly improved signal quality.

Photoelectron leakage into neighboring cells has been referred to as “blooming.” According to another method embodiment of the invention, the reset transistor 106 and one or more of transfer transistors 112, 114, 116, 118 may be operated in a sub-threshold-leakage mode in order to provide antiblooming protection during integration of the light signal. When one or more of the transfer transistors 112, 114, 116, 118 is held in sub-threshold conduction, electron leakage from one or more saturated photodiodes 122, 124, 126, 128 may be routed to the shared sense node 120 and drained through the cell high node 134. In this manner, blooming may be suppressed. Likewise, the reset transistor 106 alone may be operated in a sub-threshold leakage mode in order to avoid electron leakage from a saturated shared sense node 120 into neighboring shared sense nodes associated with neighboring CMOS image sensors 100-2 to 100-N. According to one embodiment, the cell high node 134, which is connected to the cell high signal 152, provides a path for excess electrons to drain from one or more saturated photodiodes 122, 124, 126, 128 and/or the saturated shared sense node 120. In this way, the image sensor circuit 100-1 of one embodiment may provide protection against blooming.

As discussed above in conjunction with FIGS. 2A-2D, the depicted timing diagrams illustrate an exemplary method embodiment of the invention whereby the charges acquired by each photodiode 122, 124, 126, 128 are separately processed and read by activating the gates of the transfer transistors 112, 114, 116, 118 during separate timing events. However, according to another method embodiment of the present invention, for monochrome usage, a black and white operation of the image sensor circuit 100-1 using a group of pixels 101-1 may provide increased low light level sensitivity at lower resolutions (such as in a mega-pixel resolution image sensing device that converts down to VGA resolution) by binning together the pixels 132, 134, 136, 138 associated with each photodiode 122, 124, 126, 128. According to one embodiment, the charges acquired by each photodiode 122, 124, 126, 128 may be combined into a combined charge signal at the shared sense node 120 by activating the gates of the transfer transistors 112, 114, 116, 118 at the same time, thereby transferring the charge from each of the photodiodes 122, 124, 126, 128 into a single charge signal at the shared sense node 120. The combined charge signal at the shared sense node 120 can then be read by the sample and hold circuit 130. In this particular example, the four pixels associated with four photodiodes 122, 124, 126, 128 are combined and treated as one larger pixel, resulting in a larger voltage swing at the shared sense node 120 and allowing increased low light sensitivity (with approximately ¼ the effective resolution of the overall array). In a similar manner, pairs of pixels can be combined to increase low light sensitivity. For example, two photodiodes 332, 326 can be summed into one “larger pixel” and two other photodiodes 324, 328 can be summed according to yet another embodiment of the present invention.

In one embodiment, the charges associated with the photodiodes 122, 124, 126, 128 are combined in the analog domain, e.g., at the shared sense node 120. Noise associated with the combined charge signal of such an embodiment may be reduced, resulting in further improved image quality. In addition, summing in the analog domain may reduce the amount of digital data that must be produced and processed by imager circuitry, which may result in power savings. By contrast, combining the charge signals associated with the photodiodes 122, 124, 126, 128 after conversion to the digital domain, i.e., after processing by the sample and hold circuit 130, may result in a combined signal with higher noise.

According to another embodiment of the invention, circuitry associated with the sample and hold circuit 130 can be shared between the pixels 332, 334, 336, 338 to provide further silicon area savings. In connection with one embodiment, there may be one sample and hold circuit 130 for every column of pixels. In connection with another embodiment, the sample and hold circuit 130 may be shared between two adjacent columns, resulting in a savings of layout area for the column circuits. According to this particular embodiment, the sample and hold circuit 130 may operate in an interlaced manner (e.g., processing and transferring the signals associated with one photodiode 122, clearing the sample and hold circuit 130, and then processing and transferring the signals associated with a second photodiode 124). Such an embodiment may allow the silicon area consumed by the sample and hold circuit 130 to be reduced.

According to yet another embodiment of the present invention, the voltages supplied via the cell high signal 152, the row reset signal 150, the Txfr1 signal 142, the Txfr2 signal 144, the Txfr3 signal 146, and the Txfr4 signal 148 maybe programmable and variably defined in order to provide an efficient transfer of charge from each photodiode 122, 124, 126, 128 to the sample and hold circuit 130, as well as an efficient means for resetting the shared sense node 120. For example, the low voltage level may be zero volts and the high voltage level may be four volts. Furthermore, the high voltage level and/or the low voltage level of each of the following signals: cell high 152, row reset 150, Txfr1 142, Txfr2 144, Txfr3 146, and Txfr4 148 may be variably defined. In this way, variations, such as those created during fabrication of an image sensor circuit 100-1 can be compensated for, thereby providing increased performance and yield.

By applying a sufficiently high voltage (e.g., 4.5 volts in connection with certain embodiments) to a gate of a transfer transistor 112, 114, 116, 118, the corresponding photodiode 122, 124, 126, 128 according to one embodiment may be fully depleted. And in accordance with embodiments of the present invention, a voltage applied to a transfer gate may be programmable and adjustable to obtain transfer of all charge captured on a photodiode 122, 124, 126, 128 while also saving power. In certain embodiments, waveforms other than a square or notch may be used in connection with the following signals: cell high 152, row reset 150, Txfr1 142, Txfr2 144, Txfr3 146, and Txfr4 148. For example, a transfer signal (e.g., Txfr1 142, Txfr2 144, Txfr3 146, or Txfr4 148) may initially be a high voltage level sufficient to empty the corresponding photodiode, and may then be lowered using a sawtooth signal pattern.

FIG. 3 is an illustration of a repeating four-pixel shared layout 300, which would form the imaging array with a CMOS image sensor circuit 100-1 as shown in FIG. 1. The repeating four-pixel shared layout 300 shown in FIG. 3 is drawn approximately to scale. The layout has been simplified to illustrate one example of how sharing can be implemented while achieving a high fill factor. Dimension “a” indicates that the pixels 332, 334, 336, 338 of the repeating four-pixel shared layout 300 have a pitch of about 3 microns (using typical 0.18 micron CMOS design rules). In this embodiment, the fill factor of the pixels is at least about 50% (i.e., the detecting areas 322, 324, 326, 328 occupy at least about 50% of the entire planform area or footprint of the repeating four-pixel shared layout 300). The detecting areas 322, 324, 326, 328 and transfer gates 304, 306, 308, 310 shown in FIG. 3 may correspond, respectively, with the photodiodes 122, 124, 126, 128 and transistors 112, 114, 116, 118 shown in FIG. 1.

In FIG. 3, detecting area 322 and transfer gate 304 are associated with pixel 332, detecting area 324 and transfer gate 306 are associated with pixel 334, detecting area 326 and transfer gate 308 are associated with pixel 336, and detecting area 328 and transfer gate 310 are associated with pixel 338. According to one embodiment, these four pixels 332, 334, 336, 338 are arranged in a Bayer pattern—two pixels 332, 338 are used to detect green, one pixel 334 to detect blue, and one pixel 336 to detect red. Circuit region 302 corresponds to the circuit area associated with the shared readout circuit 102 shown in FIG. 1, and a contact 320 situated near the center of the repeating four-pixel shared layout 300 corresponds to the shared sense node 120 shown in FIG. 1. The contact 320 is connected to the gate of the source follower transistor 108 and the shared sense node 120 that are shown in the schematic of FIG. 1.

As shown in FIG. 3, detecting area 322 is connected to the contact 320 through a transfer device segment 304 and N doped active segment 312. One transfer device segment 304 may correspond with a first transfer transistor 112 shown in FIG. 1. Detecting area 324 is connected to the contact 320 through another transfer device segment 306 and N doped active segment 314. This transfer device segment 306 may correspond with the second transfer transistor 114 shown in FIG. 1. Detecting area 326 is connected to the contact 320 through yet another transfer device segment 308 (third transfer transistor 116 shown in FIG. 1) and N doped active segment 312. Detecting area 328 is connected to the contact 320 through still another transfer device segment 310 (fourth transfer transistor 118 shown in FIG. 1) and N doped active segment 314. As a result of the arrangement of the repeating four-pixel shared layout 300 (wherein the contact 320 is situated near a center location), a high degree of symmetry between the pixels 332, 334, 336, 338 may be achieved, further improving image quality produced by the image sensor circuit 100-1.

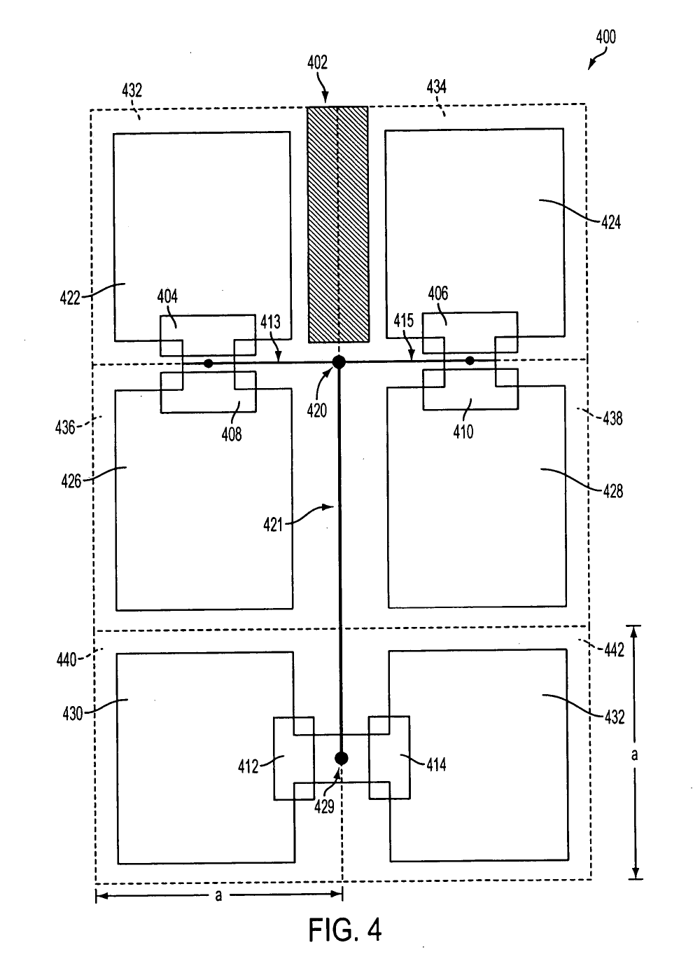

FIG. 4 shows a diagram of a portion of another semiconductor chip 400 with a sensor circuit according to the present invention. This embodiment of a semiconductor chip 400 includes four pixels 432, 434, 436, 438 arranged as described in connection with the repeating four-pixel shared layout 300 shown in FIG. 3. In addition, semiconductor chip 400 includes two more pixels 440, 442. Detecting area 422 and transfer gate 404 are associated with pixel 422, detecting area 424 and transfer gate 406 are associated with pixel 434, detecting area 426 and transfer gate 408 are associated with pixel 436, detecting area 428 and transfer gate 410 are associated with pixel 438, detecting area 430 and transfer gate 412 are associated with pixel 440, and detecting area 432 and transfer gate 414 are associated with pixel 442. In such an embodiment, segments 413 and 415 may be metal interconnects. Two pixels 440, 442 may share a common reset node 429, which may be connected to the shared sense node 420 through a metal line segment 421. Circuit region 402 corresponds to a circuit area associated with a shared readout circuit 102 as shown in FIG. 1, and the contact 420 corresponds to the shared sense node 120 shown in FIG. 1. In such an embodiment, the contact 420 may be a metal level.

In the repeating four-pixel shared layout 300 shown in FIG. 3, the shared sense node 320 is preferably connected to the transfer gates 304, 306, 308, 310 of the individual pixels 332, 334, 336, 338 via active interconnect segments 312, 314. In the embodiment of a semiconductor chip 400 shown in FIG. 4, it may be preferable to use one or more metal interconnects to minimize any added capacitance from having a long active interconnect. Such an additional parasitic capacitance may reduce the magnitude of the signal swing on the shared sense node 420.

The semiconductor chip 400 shown in FIG. 4 is drawn approximately to scale. Dimension “a” shown in FIG. 4 indicates that the pixels 432, 434, 436, 438, 440, 442 have a pitch of about 3 microns (using typical 0.18 micron CMOS design rules). In accordance with one embodiment, this type of pixel arrangement may be scaled to smaller pitches with a high fill factor, using more advanced design rules, due to the efficiency of the shared layout.

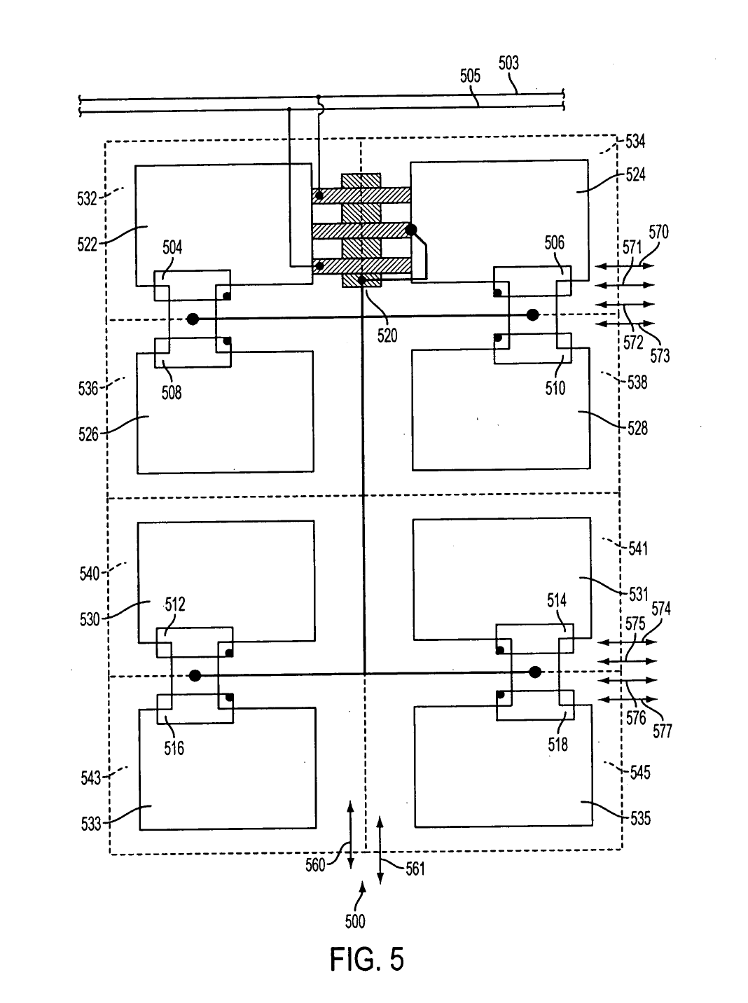

FIG. 5 shows a diagram of a portion of yet another semiconductor chip 500 with an image sensor circuit according to the present invention. This embodiment of a semiconductor chip 500 includes four pixels 532, 534, 536, 538 arranged as described in connection with the repeating four-pixel shared layout 300 shown in FIG. 3. In addition, semiconductor chip 500 includes four more pixels 540, 541, 543, 545. Detecting area 522 and transfer gate 504 are associated with pixel 532, detecting area 524 and transfer gate 506 are associated with pixel 534, detecting area 526 and transfer gate 508 are associated with pixel 536, detecting area 528 and transfer gate 510 are associated with pixel 538, detecting area 530 and transfer gate 512 are associated with pixel 540, detecting area 531 and transfer gate 514 are associated with pixel 541, detecting area 533 and transfer gate 516 are associated with pixel 543, and detecting area 535 and transfer gate 518 are associated with pixel 545. In such an embodiment, the connections between the master reset node 520 and the transfer gates 504, 506, 508, 510, 512, 514, 516, 518 may preferably be accomplished by metal line segments. Also in such an embodiment, the contact 520 may be a metal level. This semiconductor chip 500 further includes two vertical bus lines 560, 561 (indicated in FIG. S but, for clarity, not shown in their entirety), a reset node (not shown for clarity), and horizontal bus lines 570, 571, 572, 573, 574, 575, 576, 577 (indicated in FIG. 5 but not shown in their entirety). Horizontal bus lines 570, 571, 572, 573 may provide switching to transfer gates for the photodiodes of four pixels 532, 534, 536, 538, while horizontal bus lines 574, 575, 576, 577 may provide switching to transfer gates for the photodiodes of another four pixels 540, 541, 543, 545. The embodiment shown in FIG. S also includes a wire 503 connected to a master select gate and a wire 505 connected to a master reset gate.

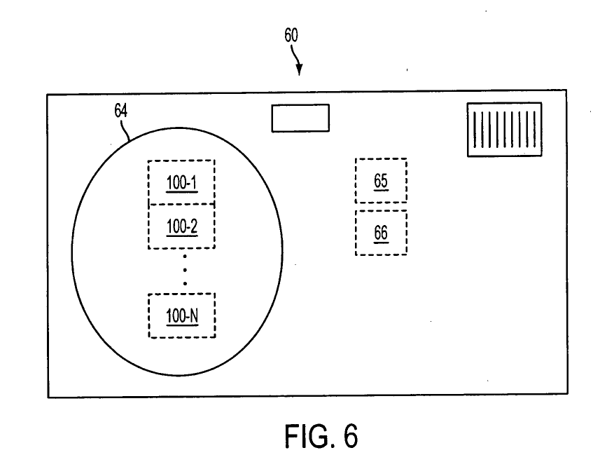

FIG. 6 shows a digital camera 60 according to one embodiment of the present invention. This digital camera 60 may include a number of image sensor circuits 100-1 to 100-N that form a lens or picture capturing device 64. The digital camera 60 of FIG. 6 may also include video/image processing circuitry 65 and a memory device 66.

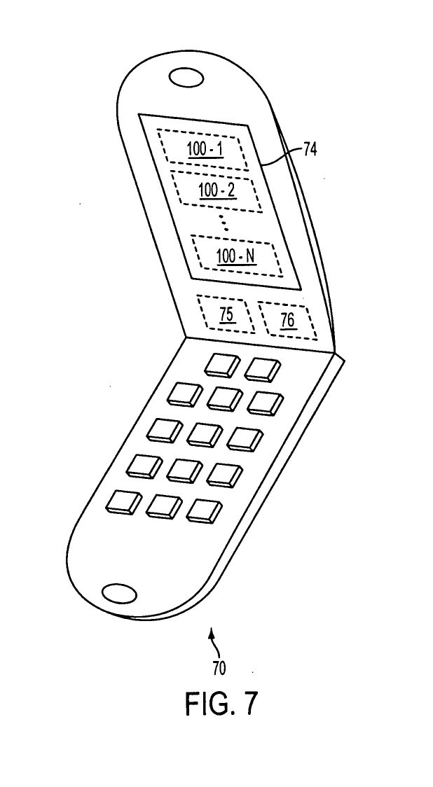

FIG. 7 shows a mobile phone 70 according to one embodiment of the present invention. This mobile phone 70 may include a number of image sensor circuits 100-1 to 100-N that form a lens or picture capturing device 74. The mobile phone 70 of FIG. 7 may also include video/image processing circuitry 75, and a memory device 76.

1. A device, comprising:
a plurality of pixels, wherein each pixel comprises a charge transfer device and a photodetector, and each of the plurality of pixels has a pitch of about 3 microns or less; and
a select transistor, a reset transistor, a source follower transistor, and a sense node, wherein the select transistor, the reset transistor, the source follower transistor, and the sense node are shared by the plurality of pixels.

2. The device of claim 1, wherein each of the plurality of photodetectors comprises a photodiode.

3. The device of claim 1, further comprising a common bus coupled with a readout circuit.

4. The device of claim 1, wherein each of the plurality of charge transfer devices transfers a charge collected by a corresponding one of the plurality of photodetectors to the shared sense node during separate timing events.

5. The device of claim 1, wherein each of the plurality of charge transfer devices transfers a charge collected by a corresponding one of the plurality of photodetectors to the shared sense node during one timing event.

6. The device of claim 3, wherein the select transistor is configured to transduce a charge signal from the shared sense node to the common bus to detect a reference charge in the shared sense node during a first timing event, and to detect a final charge associated with at least one of the plurality of photodetectors during a second timing event.

7. The device of claim 1, wherein the plurality of photodetectors comprises a first photodetector, a second photodetector, a third photodetector, and a fourth photodetector, wherein the first, second, third, and fourth photodetectors are arranged in a Bayer pattern.

8. The device of claim 7, wherein the shared sense node is situated near a center of the Bayer pattern formed by said first, second, third, and fourth photodetectors.

9. The device of claim 1, wherein at least one of the plurality of charge transfer devices can be operated in a sub-threshold leakage mode.

10. The device of claim 1, wherein a low voltage state of a gate of at least one of the charge transfer devices is set to provide antiblooming protection.

11. The device of claim 10, wherein the reset transistor can be operated in a sub-threshold leakage mode, and a voltage applied to the reset transistor can be variably defined or fixed.

12. The device of claim 1, wherein the device comprises a CMOS image sensing device.

13. The device of claim 1, wherein the plurality of pixels are adjacent to one another.

14. The device of claim 1, wherein the plurality of pixels comprises four pixels.

15. The device of claim 1, wherein the plurality of pixels comprises six pixels.

16. The device of claim 1, wherein the plurality of pixels comprises eight pixels.

17. The device of claim 1, wherein a fill factor for the plurality of pixels is at least about fifty percent.

18. A digital camera comprising the device of claim 1.

19. An imaging device comprising the device of claim 1, wherein said imaging device has a noise suppression characteristic of about 10 electrons one-sigma or less.

20. A mobile phone comprising the device of claim 1.

21. The device of claim 1, wherein the source follower transistor has a gate coupled with the sense node.

22. The device of claim 1, wherein each photodetector is capable of being substantially fully depleted and each charge transfer device is capable of transferring substantially all of a charge presented thereto.

23. An active pixel CMOS image sensor circuit, comprising:
a plurality of pixels, each pixel comprising a photodiode coupled with a transfer transistor;
a shared sense node coupled with each of the transistors;
a reset transistor having a source coupled with the shared sense node;
a source follower transistor having a drain coupled with a drain of the reset transistor and a gate coupled with the shared sense node; and
a select transistor having a drain coupled with a source of the source follower transistor, wherein the select transistor, the reset transistor, the source follower transistor, and the sense node are shared by the plurality of pixels, wherein each of the plurality of pixels has a pitch of about three microns or less, and wherein each photodetector is capable of being substantially fully depleted and each charge transfer device is capable of transferring substantially all of a charge presented thereto.

24. A digital camera comprising the active pixel CMOS image sensor circuit of claim 23.

25. A mobile phone comprising the active pixel CMOS image sensor circuit of claim 23.

26. The active pixel CMOS image sensor circuit of claim 23, wherein a fill factor for the plurality of pixels is at least about fifty percent.

27. An imaging device comprising the active pixel CMOS image sensor circuit of claim 23, wherein said imaging device has a noise suppression characteristic of about 10 electrons one-sigma or less.

28. A shared readout circuit for reading a plurality of photodetectors, the shared readout circuit comprising:
a shared sense node coupled with a plurality of transfer transistors, each of the plurality of transfer transistors configured to transfer substantially all of a charge from a corresponding one of the photodetectors to the shared sense node and connecting a corresponding one of the plurality of photodetectors to the shared sense node, the shared sense node configured to store a charge collected by each of the plurality of photodetectors;
a reset transistor, a source follower transistor, and a select transistor, the reset transistor being connected to the shared sense node and configured to reset the shared sense node, the source follower transistor having a gate connected to the shared sense node, and the select transistor connecting the source follower transistor to a common bus.

29. The shared readout circuit of claim 28, wherein the common bus is further connected to a readout circuit, the readout circuit configured to determine the charge collected by each of the plurality of photodetectors.

30. The shared readout circuit of claim 28, wherein each of the plurality of transfer transistors transfers a charge collected by a corresponding one of the plurality of photodetectors to the shared sense node during separate timing events.

31. The shared readout circuit of claim 28, wherein each of the plurality of transfer transistors transfers a charge collected by a corresponding one of the plurality of photodetectors to the shared sense node during one timing event.

32. The shared readout circuit of claim 28, wherein the select transistor is configured to transfer a charge from the shared sense node to the common bus to detect a reference charge in the shared sense node during a first timing event and to detect a final charge associated with at least one of the plurality of photodetectors during a second timing event.

33. A CMOS image sensor circuit, comprising:
a plurality of photodiodes, each of the plurality of photodiodes associated with a pixel of an imaging array, said pixel having a pitch of about 3 microns or less;
a plurality of transfer transistors, each of the plurality of transfer transistors connecting a corresponding one of the plurality of photodiodes to a shared sense node, the shared sense node configured to store a charge collected by each of the plurality of photodiodes;
a shared readout circuit comprising a reset transistor, a source follower transistor, and a select transistor, the reset transistor being connected to the shared sense node and configured to reset the shared sense node, the source follower transistor having a gate connected to the shared sense node, and the select transistor connecting the source follower transistor to a common bus.

34. The CMOS image sensor circuit of claim 33, wherein the common bus is further connected to a readout circuit.

35. The CMOS image sensor circuit of claim 33, wherein the select transistor is configured to transfer a charge from the shared sense node to the common bus to detect a reference charge in the shared sense node during a first timing event and to detect a final charge associated with at least one of the plurality of photodetectors during a second timing event.

36. A CMOS image sensor circuit comprising a group of four photodiodes that share a common readout pathway through a common sense node, wherein each of the photodiodes is connected to the common sense node through an individual transfer device and is associated with a pixel that has a pitch of about 3 microns or less, the common sense node is connected to a common source follower FET which is selected for readout by a common select FET, and the common sense node is connected to a common reset FET to establish positive potential on the sense node and each photodiode.

37. The CMOS image sensor circuit of claim 36, wherein the group of four photodiodes are arranged in a Bayer pattern.

38. The CMOS image sensor circuit of claim 36, wherein the photodiodes are fully depleted in normal reset operations.

39. The CMOS image sensor circuit of claim 36, wherein a complex waveform voltage or a variable voltage is applied to the transfer FETs during charge transfer.

40. The CMOS image sensor circuit of claim 36, wherein a variable voltage or complex waveform voltages is applied to the transfer FETs and/or the reset FET during integration to provide antiblooming protection.

41. The CMOS image sensor circuit of claim 36, wherein readout of each pixel occurs through a column circuit in which a readout function is provided for each column of the photodiodes.

42. The CMOS image sensor circuit of claim 36, wherein readout of each pixel occurs through a column circuit in which a readout function is shared between paired columns of photodiodes defined by the group of four photodiodes.

43. The CMOS image sensor circuit of claim 36, wherein a readout function is shared with multiple columns of the group of four photodiodes.

44. The CMOS image sensor circuit of claim 36, further comprising a control logic device to allow analog sampling of multiple photodiodes to the common sense node and at the same time to provide analog summation of charges collected.
